(19) United States
(12) Patent Application Publication
(10) Pub. No.: US 2016/0021766 A1
(43) Pub. Date: Jan. 21, 2016

(54) DUAL PORTABLE ELECTRONIC DEVICE CARRYING CASE

(71) Applicant: Vikramaditya JAIN, New Delhi (IN)

(72) Inventor: Vikramaditya JAIN, New Delhi (IN)

(21) Appl. No.: 14/331,832

(22) Filed: Jul. 15, 2014

(51) Int. Cl. H05K 5/00; A45C 11/00

(52) U.S. Cl. CPC H05K 5/0086; A45C 11/00; A45C 2011/003

(57) ABSTRACT

A portable electronic device carrying case is disclosed. The carrying case can include a front panel; a back panel; a partition disposed between the front panel and the back panel; and a retaining structure extending between bottom portions of the front panel and the back panel, where the front panel, back panel, and partition, are coupled along opposing, longitudinal edges. The carrying case can also include first and second storage volumes. The first storage volume can be accessible from a first opening at an end opposite the retaining structure, where the first storage volume formed by the front panel, the partition, and the retaining structure. The second storage volume can be accessible from a second opening at an end opposite the retaining structure, where the second storage volume formed by the back panel, the partition, and the retaining structure.

### FIELD OF THE INVENTION

The present invention relates generally to a carrying case for mobile devices, particularly, a carrying case for storing multiple mobile devices.

### BACKGROUND

Mobile devices have become the ubiquitous in our society. There are a broad variety of carrying cases available for the different mobile devices, including smart phones, mini-tablets, and tablets. These carrying cases provide a number of functions, including protecting the mobile devices, accommodating the particular geometry of the mobile device, and allowing users to express themselves.

### SUMMARY

In one embodiment, a portable electronic device carrying case is disclosed. The carrying case can include a front panel; a back panel; a partition disposed between the front panel and the back panel; and a retaining structure extending between bottom portions of the front panel and the back panel, where the front panel, back panel, and partition, are coupled along opposing, longitudinal edges. The carrying case can also include first and second storage volumes. The first storage volume can be accessible from a first opening at an end opposite the retaining structure, where the first storage volume formed by the front panel, the partition, and the retaining structure. The second storage volume can be accessible from a second opening at an end opposite the retaining structure, where the second storage volume formed by the back panel, the partition, and the retaining structure.

These and other features, objects and advantages of the present invention will become more apparent to one skilled in the art from the following description and claims when read in light of the accompanying drawings.

### BRIEF DESCRIPTION OF THE DRAWINGS

FIG. 1 is a perspective view of a portable electronic device carrying case as described herein.

FIG. 2 is a front view of the carrying case of FIG. 1 with a smart phone in the first storage volume.

FIG. 3 is a left side view of the carrying case of FIG. 1 loaded with two smart phones.

FIG. 4 is a top view of the carrying case of FIG. 1 loaded with two smart phones.

FIG. 5 is a bottom view of the carrying case of FIG. 1 loaded with two smart phones.

FIG. 6 is a back view of the carrying case of FIG. 1 with a smart phone in the second storage volume.

FIG. 7 is a cross-sectional view of the carrying case of FIG. 2 taken along cut line 7-7, with the smart phones removed.

FIG. 8 is a cross-sectional view of the carrying case of FIG. 2 taken along cut line 8-8, with the smart phones removed.

FIG. 9 is the cross-sectional view of FIG. 8, except it is an embodiment where the bottom edge of the partition is a free edge.

FIG. 10 is a close-up, cross-sectional view of the partition of FIG. 9, where the partition reinforcing material is formed of two reinforcing materials that are coupled.

FIG. 11 is the cross-section view of FIG. 8, except that the reinforcing materials are dual-layer reinforcing materials and the facings are wrapped over the individual reinforcing layers.

### DETAILED DESCRIPTION

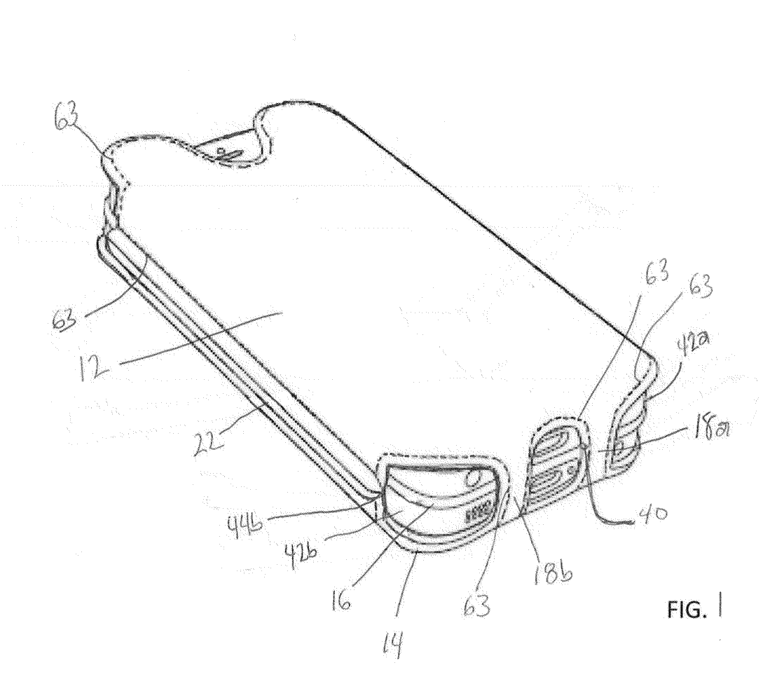

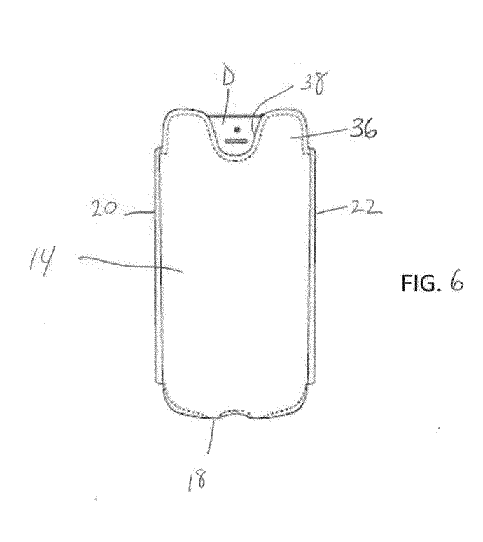

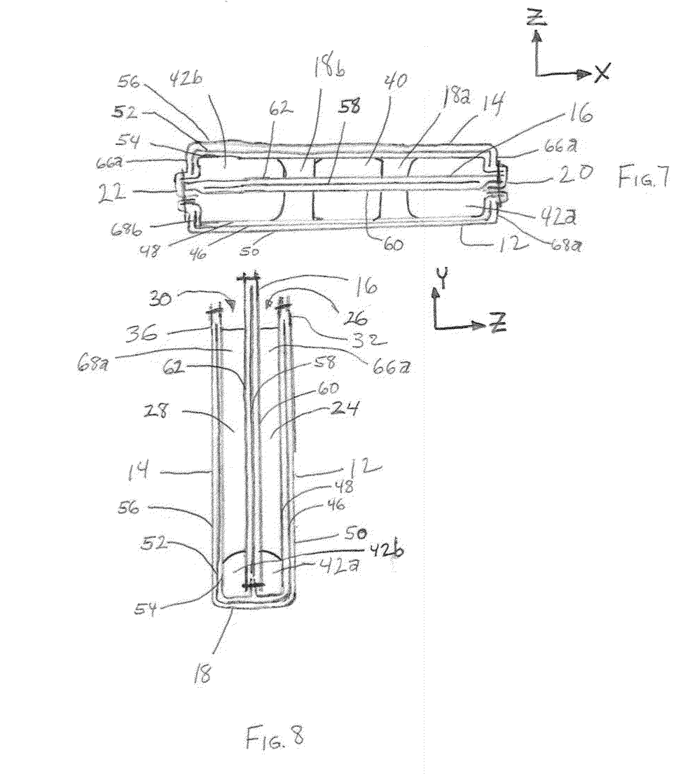

As shown in FIGS. 1-11, a portable electronic device carrying case 10 is disclosed. The carrying case 10 can include a front panel 12; a back panel 14; a partition 16 disposed between the front panel 12 and the back panel 14; and a retaining structure 18 extending between bottom portions of the front panel 12 and the back panel 14. The front panel 12, back panel 14, and partition 16, are coupled along opposing, longitudinal edges 20, 22. As used herein, “longitudinal” refers to the length of the carrying case 10, which is designated by the Y-axis.

In some embodiments, the carrying case 10 includes a first storage volume 24 that is accessible from a first opening 26 at an end opposite the retaining structure 18. In some embodiments, the first storage volume 24 is formed by the front panel 12, the partition 16, and the retaining structure 18. The first storage volume 24 can be adapted so that a portable electronic device (D1) can slide into the first storage volume 24 through the first opening 26. In some embodiments, there are other openings (e.g., 40, 42) in the first storage volume 24; however, the other openings are small enough that a portable electronic device (D1) stored in the first storage volume 24 cannot pass through them.

In some embodiments, the carrying case 10 includes a second storage volume 28 accessible from a second opening 30 at an end opposite the retaining structure 18. In some embodiments, the second storage volume 28 is formed by the back panel 14, the partition 16, and the retaining structure 18. The second storage volume 28 can be adapted so that a portable electronic device (D2) can slide into the second storage volume 28 through the second opening 30. In some embodiments, there are other openings (e.g., 40, 42) in the second storage volume 28; however, the other openings are small enough that a portable electronic device (D2) stored in the second storage volume 28 cannot pass through them.

In some embodiments, (a) a top portion 32 of the front panel 12 comprises a front cut-out 34, (b) a top portion 36 of the back panel 14 comprises a back cut-out 38, or (c) both (a) and (b). In some embodiments, the front cut-out 34, the back cut-out 38, or both, are centered laterally (X-axis) along a top portion 32, 36 of the front and back panels 12, 14, respectively. In some embodiments, the front cut-out 34, the back cut-out 38, or both, are adapted for the user to contact a portion of a portable electronic device (D) stored in the first and/or second storage volume 24, 28, respectively, with a thumb of the user. This allows the user to exert force on the portable electronic device (D) to assist with removing the portable electronic device from the applicable storage volume 24, 28. In some embodiments, the cut-outs 34, 38 also expose a speaker of the portable electronic devices (D1, D2).

In some embodiments, as shown in FIGS. 5 & 7, the retaining structure 18 is discontinuous in a lateral direction (X-direction). In some embodiments, the retaining structure 18 comprises two straps defining a central opening 40 between the straps of the retaining structure 18.

In some embodiments, the carrying case 10 includes access openings 42a, 42b laterally outside the retaining structure 18. In some embodiments, as shown in FIGS. 2, 5 & 7, a first access opening 42a extends from a strap 18a of the retaining structure to the lower extent 44a of the longitudinally coupled portion 20 of the front and back panels 12, 14. In some embodiments, as best shown in FIG. 1, a second access opening 42b extends from a strap 18b of the retaining structure to the lower extent 44b of the longitudinally coupled portion 22 of the front and back panels 12, 14.

In some embodiments, the central opening 40 and the access openings 42a, 42b can be adapted for accessing the portable electronic device. For example, in the embodiment shown in FIG. 5, the central opening 40 provides access to data transfer and charging ports (P1, P2) of the portable electronic devices (D1, D2); while the access openings 42a, 42b provide access to speakers/microphones (S1, S2) and audio jacks (A2, A1), respectively. In some embodiments, such as that of FIG. 5, the arrangement of the central opening 40 and the access openings 42a, 42b can be symmetrical about a longitudinal axis (L).

In some embodiments, the carrying case 10 is symmetrical about at least one longitudinal plane (e.g., the Y-Z plane), while the carrying case 10 is symmetrical about at least two longitudinal planes (e.g., the Y-Z plane and the Y-X plane) in some other embodiments. For example, the carrying case in FIG. 2 is symmetrical about a Y-Z plane passing through the longitudinal axis L.

In some embodiments, the front panel 12 includes a front panel reinforcing material 46 between inner and outer front facing materials 48, 50. In some embodiments, the back panel 14 includes a back panel reinforcing material 52 between inner and outer back facing materials 54, 56. In some embodiments, the partition 16 includes a partition reinforcing material 58 between front and back partition facing materials 60, 62.

In some embodiments, surfaces of the front panel 12 and the partition 16 defining the first storage volume 24 include or are formed from a screen wiping material. In some embodiments, surfaces of the back panel 14 and the partition 16 defining the second storage volume 28 include or are formed from a screen wiping material. Examples of surfaces that can include or be formed from screen wiping materials include, but are not limited to, the inner front facing 48, the inner back facing 54, and the front and back partition facings 60, 62.

As used herein, “screen wiping material” refers to materials adapted for removing oils and other residue from the touch screen of a portable electronic device. Examples of screen wiping materials include, but are not limited to, lint free fabric (e.g., microfiber fabric), suede, and other like materials. Examples of materials useful for forming microfibers include, but are not limited to, polyesters, natural fibers (e.g., cotton, flax, hemp, jute, ramie, wool, angora wool, cashmere, mohair, silk, etc.), polyamides (e.g., nylon, Kevlar®, Nomex®, trogamide), or a conjugation of polyester, polyamide, and polypropylene (e.g., Prolen®). As used herein, “microfiber” refers to synthetic fibers that are no more than 1.3 denier or no more than 1.0 denier.

In some embodiments, the outer front facing 50 and the outer back facing 56 can be made of a flexible material. Examples of materials useful for the outer front facing include, but are not limited to, leather, synthetic leather, vinyl, fabrics, and other suitable materials. Examples of materials useful in fabrics for the facings include, but are not limited to, synthetic fibers and natural fibers, such as, cotton, flax, hemp, jute, ramie, wool, angora wool, cashmere, mohair, silk, etc. In some embodiments, a thickness of the outer front facing 50, the outer back facing 56, or both, ranges from 1.0 mm and 1.5 mm, or ranges from 1.1 mm and 1.4 mm. In some embodiments, the outer front facing 50 and the outer back facing 56 are formed of a continuous leather material.

In some embodiments, the reinforcing materials 46, 52, 58 can be independently formed of one or more sheets of materials formed from plastic, wood, metal, leather, fabric, or a combination thereof. In some embodiments, the reinforcing materials 46, 52, 58 are single layers of material, while the reinforcing materials 46, 52, 58 are multi-layer structures in other embodiments. An example of a dual-layer structure is shown in FIG. 11. In some embodiments, the reinforcing materials 46, 52, 58 can be formed of leather board. Where the reinforcing member is a plastic sheet or board, the reinforcing member can be formed of a material including, but not limited to, polyethylene (PE), polypropylene (PP), polystyrene (PS), polyesters, combinations thereof, and other durable polymer materials. Where the reinforcing member is a fabric, the reinforcing member can be formed of a material including, but not limited to, synthetic fibers and natural fibers, such as, cotton, flax, hemp, jute, ramie, wool, angora wool, cashmere, mohair, silk, etc. In some embodiments, the reinforcing material 46, 52, 58 is between 0.1 mm and 1.0 mm in total sheet thickness (i.e., the total thickness of the individual material sheets used to form the reinforcing material, excluding glue). In some embodiments, the front and back reinforcing materials 46, 52 are formed from two sheets of material each ranging from 0.3 mm to 0.5 mm thick. In some embodiments, the partition reinforcing material 58 is formed from two sheets of material each ranging from 0.1 mm to 0.3 mm thick.

In some embodiments, the carrying case 10 is formed from flexible materials and the reinforcing materials reduce, but do not eliminate flexibility of the respective panels 12, 14, 16. In such embodiments, it is possible to non-destructively bend the carrying case 10 so that opposing portions (e.g., 45a, 45b) of the front panel 12 touch one another.

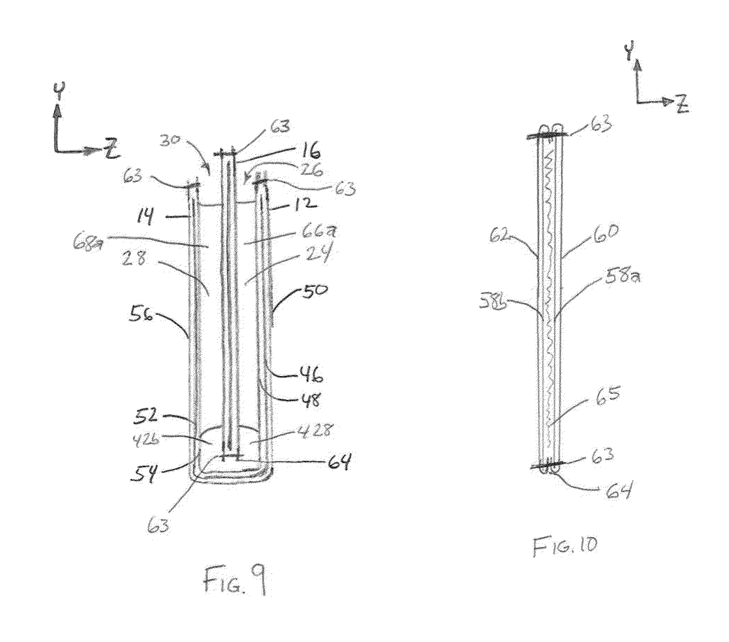

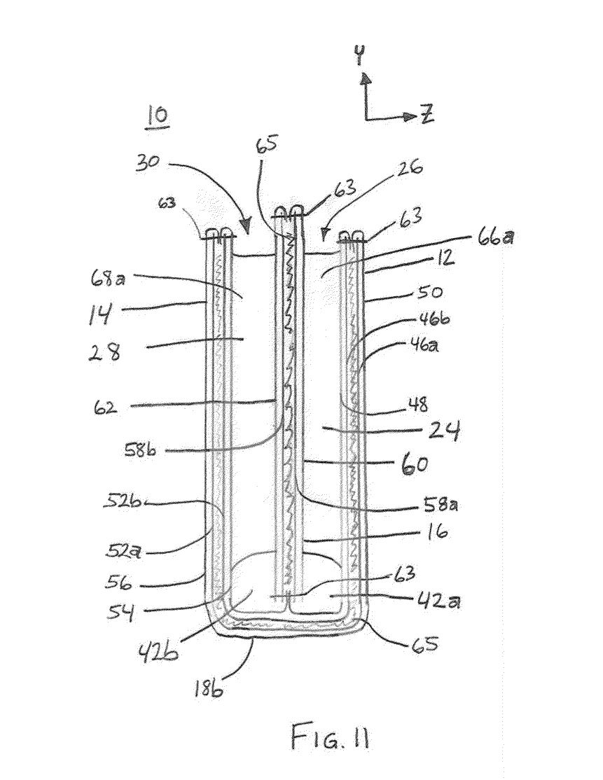

The various layers of the front panel 12, back panel 14, and the partition 16 can be joined together using a variety of techniques. For example, where the reinforcing material includes multiple layers, the reinforcing layers can be coupled together with glue 65. Similarly, the facings can be glued to the reinforcing layer(s). In addition, in some embodiments, as shown in FIG. 8, the facings can extend beyond the reinforcing material and the facings can be sewn (e.g., via stitching 63) together along one or more edges. In other embodiments, as shown in FIG. 10, the edges of each facing can be wrapped over the edges of a reinforcing material and the edges of the facing-reinforcing material composites can be coupled via glue 65 and/or stitching 63 along one or more edges.

As an example, FIG. 10 shows a close-up view of the partition 16 of FIG. 9 constructed using a multi-layer partition reinforcing material 58a, 58b. The front partition facing 60 is wrapped over the edges of the front partition reinforcing material 58a, while the back partition facing 62 is wrapped over the edges of the back partition reinforcing material 58b. The front and back partition reinforcing materials 58a, 58b are optionally coupled by glue 65. The edges of the composite partition 16, which includes the partition reinforcing material 58, and front and back partition facings 60, 62 are also held together by stitching 63. As shown in FIG. 11, similar multi-layer reinforcing material construction techniques can be used for forming the front and back panels 12, 14.

In some embodiments, the front panel 12, the back panel 14, and the retaining structure 18 comprise a continuous layer. In some embodiments, the front panel 12, the back panel 14, and the retaining structure 18 comprise more than one continuous layer. For example, in FIG. 8, the front and back panel reinforcing materials 46, 52 are continuous, and the outer front facing 50 and outer back facing 56 are continuous. In FIG. 9, the inner front facing 48 and the inner back facing 54 are also continuous.

In some embodiments, as best shown in FIG. 7, the inner and outer front facing materials 48, 50, the inner and outer back facing materials 54, 56, and the front and back partition facing materials 60,62 are coupled along respective longitudinal edges 20, 22 of each. In some embodiments, the inner and outer front facing materials 48, 50, the inner and outer back facing materials 54, 56, and the front and back partition facing materials 60,62 are coupled by stitching 63 (e.g., sewn with or without a binding).

In some embodiments, as best shown in FIG. 8, the inner front facing material 48, the inner back facing material 54, and the front and back partition facing materials 60, 62 are coupled along respective lower portions of each. In some embodiments, as best shown in FIG. 8, the inner front facing material 48, the inner back facing material 54, and the front and back partition facing materials 60, 62 are coupled by stitching 63.

In some other embodiments, as shown in FIG. 9, a lower edge of the partition 16 is a free edge 64. As used herein, “free edge” is used to refer to an edge that is not coupled to another part of the carrying case 10.

In some embodiments, as shown in FIG. 7, lateral cross-sections of the first and second storage volumes 24, 28 are generally rectangular. In some embodiments, outer portions of the front and back panel 12, 14 are bent to form front, side portions 66a, 66b and back, side portions 68a, 68b, respectively, of the rectangular lateral cross-sections of the first and second storage volumes 24, 28. In some embodiments, the front, side portions 66a, 66b can be the short sides of the generally rectangular cross-section of the first storage volume 24, while the central portion of the front panel 12 and the partition 16 can be the long sides. In some embodiments, the back, side portions 68a, 68b can be the short sides of the generally rectangular cross-section of the second storage volume 28, while the central portion of the back panel 14 and the partition 16 can be the long sides. In some embodiments, the short sides extend generally in the depth direction (Z-axis), while the long sides extend generally in the lateral direction (X-axis)

As used herein, “generally rectangular” refers to a shape having four identifiable sides, where each side is generally orthogonal (90°±10°, or 90°±5°, or 90°±2.5°) to the sides at each end thereof. Thus, as shown in FIG. 7, the actual intersection of the side can be curved or across a seam so long as the sides are generally orthogonal.

One, two, three, or all four, sides of the rectangular cross-section can be linear or generally linear. As used herein, “generally liner” is used to refer to a line that deviates no more than 10% from linear relative to the total length of the line. In some instances, generally linear includes lines that deviate no more than 5% from linear relative to the total length of the line, or lines that deviate no more than 2.5% from linear relative to the total length of the line. In other words, if a straight line is drawn between the two end points of a generally linear segment or line, the maximum orthogonal distance between the straight line and the generally linear segment will be no more than 10% of the distance between the two end points.

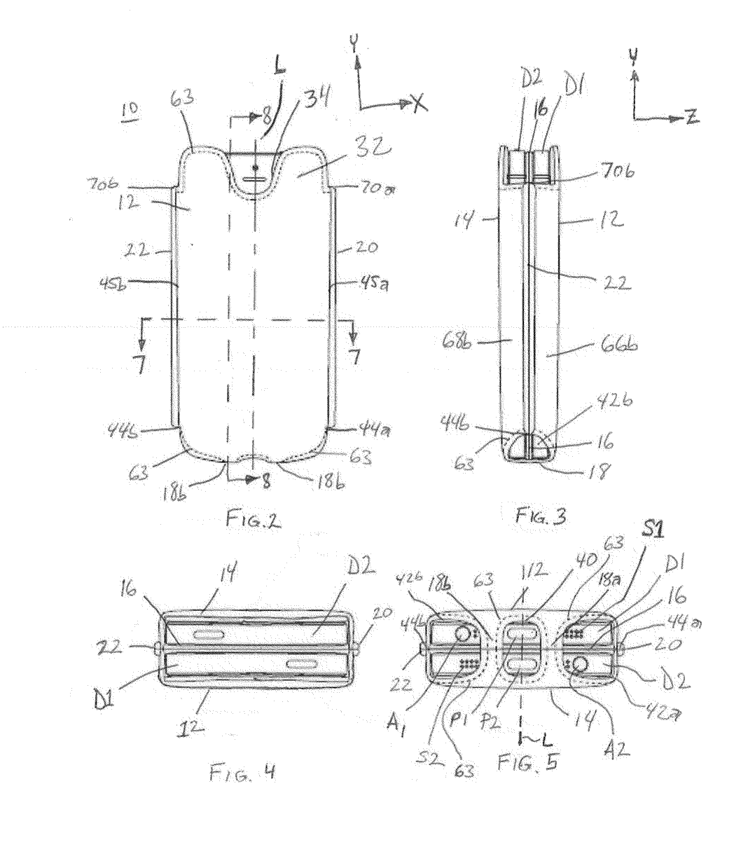

In some embodiments, as best shown in FIGS. 2 & 3, the front panel 12 and the back panel 14 extend above the upper extent 70a, 70b of the longitudinally coupled portions 20, 22 of the front panel 12 and the back panel 14. As shown in FIG. 3, in some embodiments, the partition 16 extends above the upper extent 70a, 70b of the longitudinally coupled portions 20, 22 of the front panel 12 and the back panel 14.

In some embodiments, one or both of the cut-outs 34, 38 extend below the upper edge of the partition 16. In some embodiments, one or both of the cut-outs 34, 38 extend below the upper extent 70a, 70b of the longitudinally coupled portions 20, 22 of the front panel 12 and the back panel 14.

The foregoing is provided for purposes of illustrating, explaining, and describing embodiments of this invention. Modifications and adaptations to these embodiments will be apparent to those skilled in the art and may be made without departing from the scope or spirit of this invention.

What is claimed is:

1. A portable electronic device carrying case, comprising:
a front panel;
a back panel;
a partition disposed between the front panel and the back panel;
a retaining structure extending between bottom portions of the front panel and the back panel, wherein the front panel, back panel, and partition, are coupled along opposing, longitudinal edges;
a first storage volume accessible from a first opening at an end opposite the retaining structure, said first storage volume formed by the front panel, the partition, and the retaining structure; and
a second storage volume accessible from a second opening at an end opposite the retaining structure, said second storage volume formed by the back panel, the partition, and the retaining structure.

2. The portable electronic device carrying case of claim 1, wherein a top portion of the front panel comprises a cut-out, and a top portion of the back panel comprises a cut-out.

3. The portable electronic device carrying case of claim 1, wherein the retaining structure is discontinuous in a lateral direction.

4. The portable electronic device carrying case of claim 1, wherein the retaining structure comprises two straps defining a central opening in-between.

5. The portable electronic device carrying case of claim 4, further comprising, access openings laterally outside the retaining structure.

6. The portable electronic device carrying case of claim 1, wherein surfaces of the front panel, and the partition facing the first storage volume comprise a screen wiping material.

7. The portable electronic device carrying case of claim 6, wherein surfaces of the back panel, and the partition facing the second storage volume comprise a screen wiping material.

8. The portable electronic device carrying case of claim 1, wherein said portable electronic device carrying case is symmetrical about at least one longitudinal plane.

9. The portable electronic device carrying case of claim 1, wherein the front panel, the back panel, and the retaining structure comprise a continuous layer.

10. The portable electronic device carrying case of claim 1, wherein the front panel comprises a front panel reinforcing material between inner and outer front facing materials.

11. The portable electronic device carrying case of claim 10, wherein the back panel comprises a back panel reinforcing material between inner and outer back facing materials.

12. The portable electronic device carrying case of claim 11, wherein the partition comprises a partition reinforcing material between front and back partition facing materials.

13. The portable electronic device carrying case of claim 12, wherein the inner and outer front facing materials, the inner and outer back facing materials, and the front and back partition facing materials are coupled along respective longitudinal edges of each.

14. The portable electronic device carrying case of claim 12, wherein inner front facing material, the inner back facing material, and the front and back partition facing materials are coupled along respective lower portions of each.

15. The portable electronic device carrying case of claim 1, wherein lateral cross-sections of the first and second storage volumes are generally rectangular.

16. The portable electronic device carrying case of claim 1, wherein outer portions of the front and back panel are bent to form side portions of the rectangular lateral cross-sections.

17. The portable electronic device carrying case of claim 1, wherein the front panel and the back panel extend above the upper extent of the longitudinally coupled portion of the front panel and the back panel.

18. The portable electronic device carrying case of claim 17, wherein the partition extends above the upper extent of the longitudinally coupled portion of the front panel and the back panel.

19. The portable electronic device carrying case of claim 1, wherein the retaining structure is below the lower extent of the coupled portion of the front and the back panel.

20. The portable electronic device carrying case of claim 1, wherein a lower edge of the partition is a free edge.
